(19) United States
(12) Patent Application Publication
(10) Pub. No.: US 2015/0013481 A1
(43) Pub. Date: Jan. 15, 2015

(54) MICRO-SCALE PENDULUM

(71) Applicant: HEWLETT-PACKARD DEVELOPMENT COMPANY, L.P., Fort Collins, CO (US)

(72) Inventors: James Elmer Abbott, JR., Corvallis, OR (US); John L. Williams, Corvallis, OR (US); Pavel Kornilovich, Corvallis, OR (US)

(21) Appl. No.: 14/374,110

(22) PCT Filed: Jan. 26, 2012
(86) PCT No.: PCT/US2012/022694

§ 371 Date: Jul. 23, 2014

(51) Int. Cl. G01C 19/06; G03F 7/40; C23C 16/40

(52) U.S. Cl. CPC G01C 19/065; C23C 16/40; G03F 7/40
USPC 74/5.95; 216/99

(57) ABSTRACT

A micro-scale pendulum structure. The structure includes a membrane having a peripheral support portion and an inner portion, and a micro-scale pendulum carried by the inner portion of the membrane.

### BACKGROUND

There are various applications for micro-scale pendulum structures. One such application is measuring rotation of an object. An angular distance through which a macro- or meso-scale object has rotated can be determined by a Foucault pendulum. For a micro-scale object, angular motion is calculated from measurements of rate and duration of rotation; this requires determining angular measuring coriolis forces on a system undergoing an induced symmetric stretch, and integrating over time. Micro-scale pendulum structures used in applications such as measurement of rotation include torsional springs attached to a pendulum element.

### BRIEF DESCRIPTION OF THE DRAWINGS

The figures are not drawn to scale. They illustrate the disclosure by examples.

FIGS. 1A and 1B are a side view and a top view, respectively, of a micro-scale pendulum structure according to an example.

FIG. 2 is a perspective view of the micro-scale pendulum of FIG. 1.

FIGS. 3A and 3B are another example of a top view and a cross-sectional side view, respectively, of a micro-scale pendulum.

FIG. 4 is a flowchart showing an example of a method of fabricating a micro-soak pendulum.

FIGS. 5A through 5C are flowcharts showing other examples of methods of fabricating a micro-scale pendulum.

FIG. 6 is a top view of a silicon slab on which an array of pendulum structures has been patterned.

FIGS. 7A through 7D are cross-sectional views of an example of a micro-scale pendulum at various stages of fabrication.

FIGS. 8A through 8D are cross-sectional views of an example of a micro-scale pendulum and membrane support at various stages of fabrication.

FIGS. 9-11 are side views of examples of a micro-scale pendulum.

FIG. 12 is a sectional view of an example of a micro-scale pendulum.

FIG. 13 is a top view of an example showing patterning of the membrane.

FIG. 13A is a sectional view along the line A-A in FIG. 13.

FIG. 13B is a sectional view along the line B-B in FIG. 13

### DETAILED DESCRIPTION

Illustrative examples and details are used in the drawings and in this description, but other configurations may exist and may suggest themselves. Parameters such as voltages, temperatures, dimensions, and component values are approximate. Terms of orientation such as up, down, top, and bottom are used only for convenience to indicate spatial relationships of components with respect to each other, and except as otherwise indicated, orientation with respect to external axes is not critical. For clarity, some known methods and structures have not been described in detail. Methods defined by the claims may comprise steps in addition to those listed, and except as indicated in the claims themselves the steps may be performed in another order than that given. Accordingly, the only limitations are imposed by the claims, not by the drawings or this description.

Micro-scale pendulum structures have used torsional springs and other springs such as linear springs that provide a symmetric stretching to control and detect pendulum motion. In an application of such pendulum structures, rotation of micro-scale objects is calculated from measurements of the rate of rotation and information about how long the rotation has been occurring. There has been only limited success performing direct measurement of physical properties of a system to determine the amount of rotation a micro-scale object has undergone relative to an initial reference point, resulting in a lack of precision in determining absolute rotation.

Precise microscale pendulums as in the various examples herein may be used as Foucault pendulums to directly measure rotation of a micro-scale object, for example rotation relative to an initial reference point.

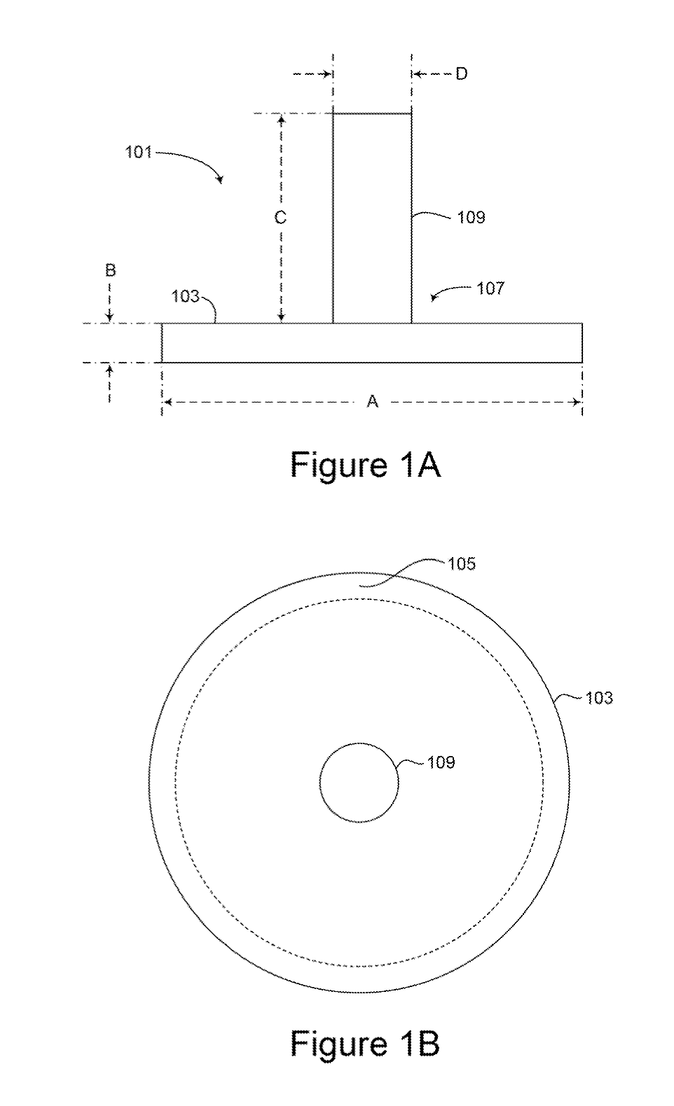

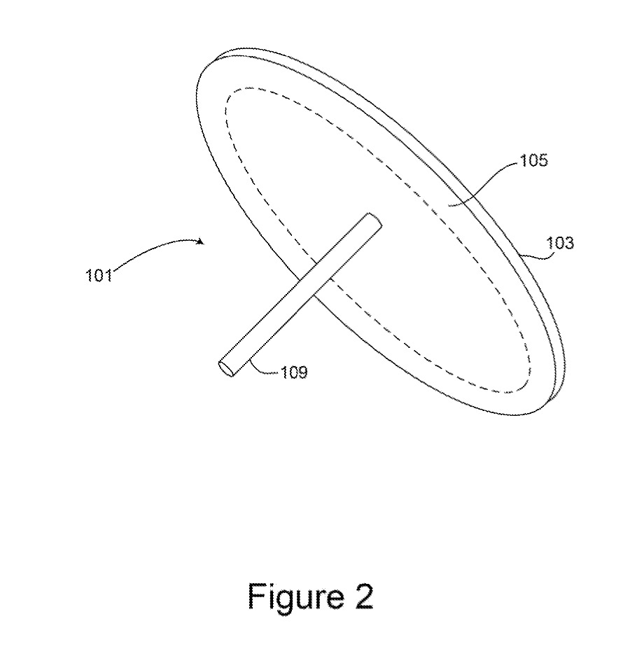

FIGS. 1A, 1B and 2 show a micro-scale pendulum structure generally 101. The structure includes a membrane 103 having a peripheral support portion 105 and an inner portion 107. A micro-scale pendulum 109 is carried by the inner portion of the membrane.

The membrane may be formed of a homogeneous amorphous film material, a polymer film, or other suitable material. In one example the pendulum comprises thermally grown oxide (TOX). The membrane may be deposited material. It may be composed of multiple materials; for example, the membrane may comprise a layered composite. The membrane may be porous.

The peripheral support portion of the membrane is not necessarily different in character from other portions of the membrane. Rather, the peripheral support portion is supported by a fixed support. For example, the peripheral support portion may be bonded to a substrate such as glass, metal, or other suitable material. In some examples the support comprises silicon or some other material that may be grown or deposited on the membrane on the same side as the pendulum or on the opposite side.

The pendulum may be formed of silicon, as in the example shown in FIG. 1, or other organic or inorganic material. It may be formed of different materials than the membrane or the substrate. It may be solid (as illustrated), or it may be hollow as will be described presently. A carbon nanotube may be used as the pendulum. The pendulum, as the membrane, may be made of multiple materials (a composite). The pendulum is shown as centered on the membrane, but this is not critical so long as the membrane is large enough relative to the pendulum that motion of the pendulum is not adversely affected by forces along the peripheral support portion of the membrane. The pendulum may be grown on the membrane or fabricated separately and bonded to the membrane.

The membrane may be continuous and smooth, or it may be patterned as a way of precisely controlling its behavior.

Dimensions and shapes are not critical. In the example as shown, the membrane and pendulum are circular in shape. The diameter A of the membrane is about 1,000 micrometers (μm), the thickness B of the membrane is about 2 μm, the length C of the pendulum is about 700 μm, the diameter D of the pendulum is about 50 μm, and the pendulum has a substantially constant diameter along its length. These parameters are not critical; the shapes and dimensions of the pendulum and the membrane may be varied depending on requirements of a specific installation.

As one example, a pendulum was constructed in which the material properties were:

TABLE 1

| Material | Modulus in MPa | Poisson's Ratio | Density in kg/(μm)³ |
|---|---|---|---|
| Si | 169,000 | 0.3 | 2.5e⁻¹⁵ |
| TOX | 73,000 | 0.16 | 2.33e⁻¹⁵ |

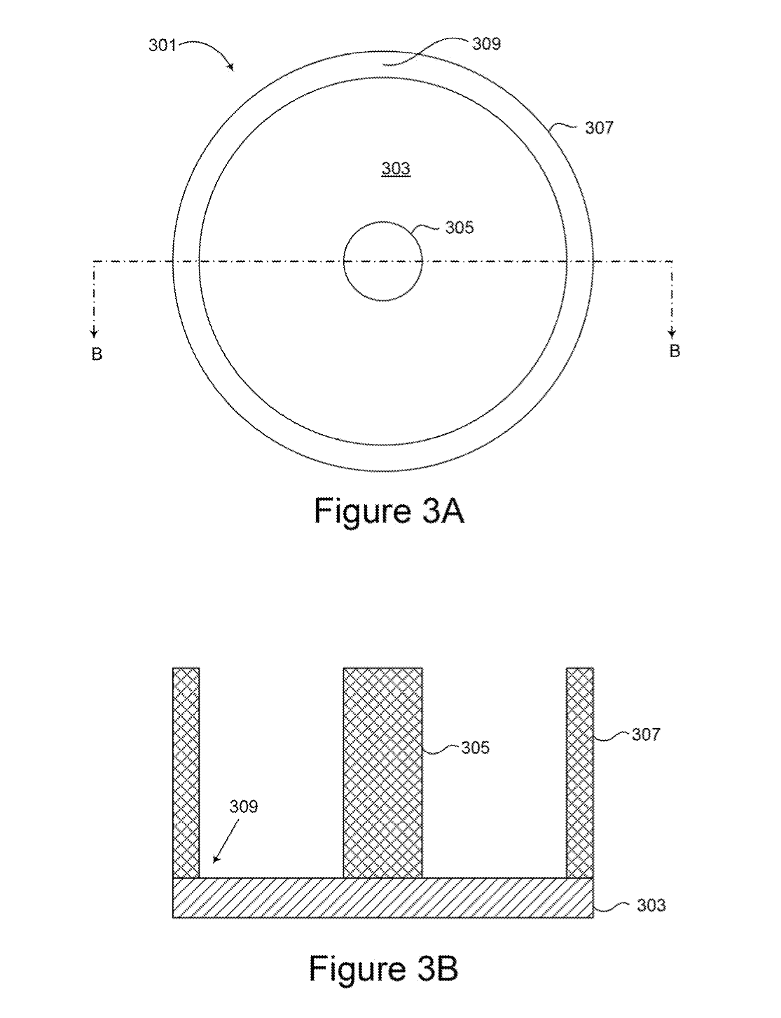

FIGS. 3A and 3B show a pendulum structure generally 301. This example includes a membrane 303, a pendulum 305 carried by the membrane, and a support 307 affixed to a support portion 309 of the membrane. The support may be formed of silicon. The support may extend around the perimeter of the membrane and surround the pendulum as shown, but this is not critical and in other examples the support may comprise one or more sections spaced around the perimeter of the membrane.

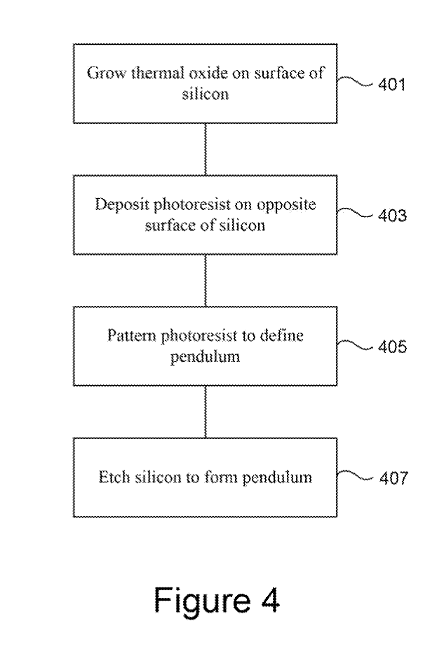

An example of a method of fabricating a micro-scale pendulum structure is shown in FIG. 4. A layer of thermal oxide (TOX) is grown (401) on a surface of a slab of silicon. Photoresist is deposited (403) on a surface of the silicon slab opposite the TOX. The photoresist is patterned (405) to define a pendulum, and the silicon is etched (407) according to the pattern defined by the photoresist to form the pendulum.

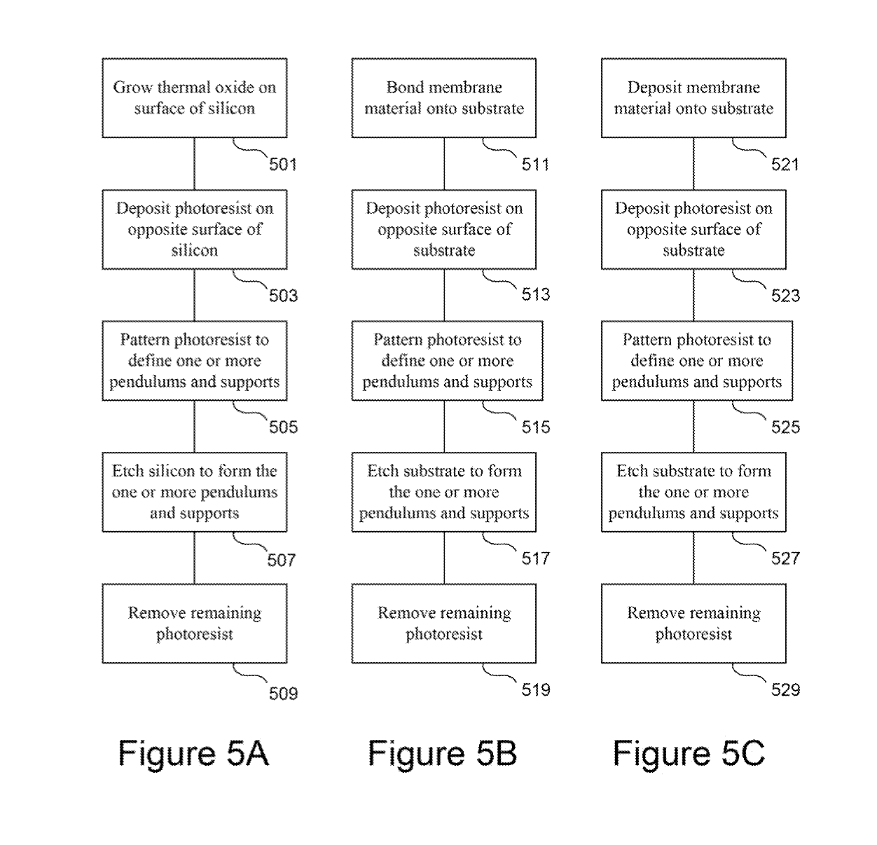

Examples of a method of fabricating a micro-scale pendulum including a support are shown in FIGS. 5A, 5B and 5C. In the example shown in FIG. 5A, a layer of TOX is grown (501) on a surface of a slab of silicon. Photoresist is deposited (503) on a surface of the silicon slab opposite the TOX. The photoresist is patterned (505) to define a pendulum and a support, and the silicon is etched (507) according to the pattern defined by the photoresist to form the pendulum and the support. Any remaining photoresist may be removed (509).

FIG. 5B shows an example in which membrane material is bonded (511) onto a substrate and FIG. 5C shows an example in which membrane material is deposited (521) onto a substrate. Subsequent steps are similar for these examples, including depositing (513 and 523) photoresist on an opposite surface of the substrate, patterning (515 and 525) the photoresist to define one or more pendulums and supports, etching (517 and 527) the substrate to form the one or more pendulums and supports, and removing (519 and 529) any remaining photoresist.

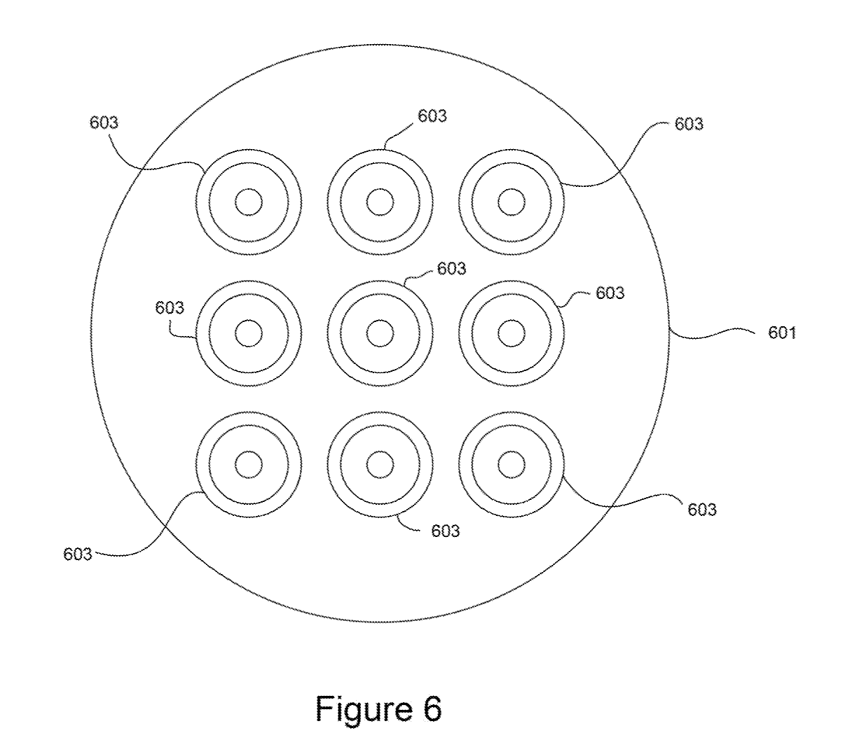

The silicon slab may be patterned to define an array of pendulums or an array of pendulums and supports rather than just one pendulum. For example, FIG. 6 shows an upper surface of a silicon slab 601 on which an array of nine pendulum structures 603, each including a support, has been patterned. After etching, the structure may be diced to provide individual pendulum structures.

The membrane may be bonded to the substrate. Glass, metal, or other material may be used for the substrate.

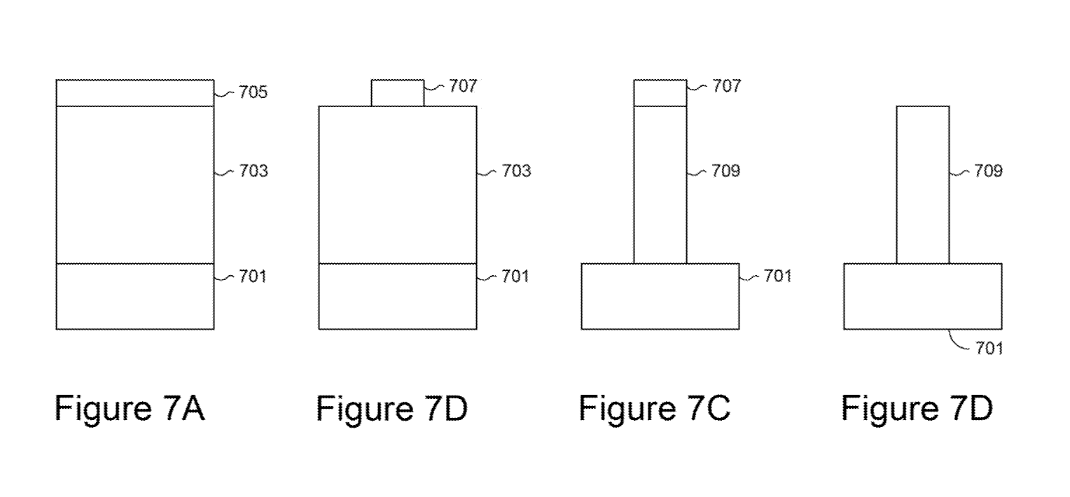

Steps in a method of fabricating a pendulum structure are shown in FIGS. 7A-7D, In FIG. 7A, a TOX layer 701 has been grown on one side of a silicon slab 703 and a layer of photoresist 705 has been deposited on the other side of the silicon slab. In FIG. 7B, the photoresist has been patterned to define an outline 707 of a pendulum. Etching has been carried out in FIG. 7C, resulting in a pendulum 709 on the TOX layer 701. Finally in FIG. 7D any remaining photoresist has been removed.

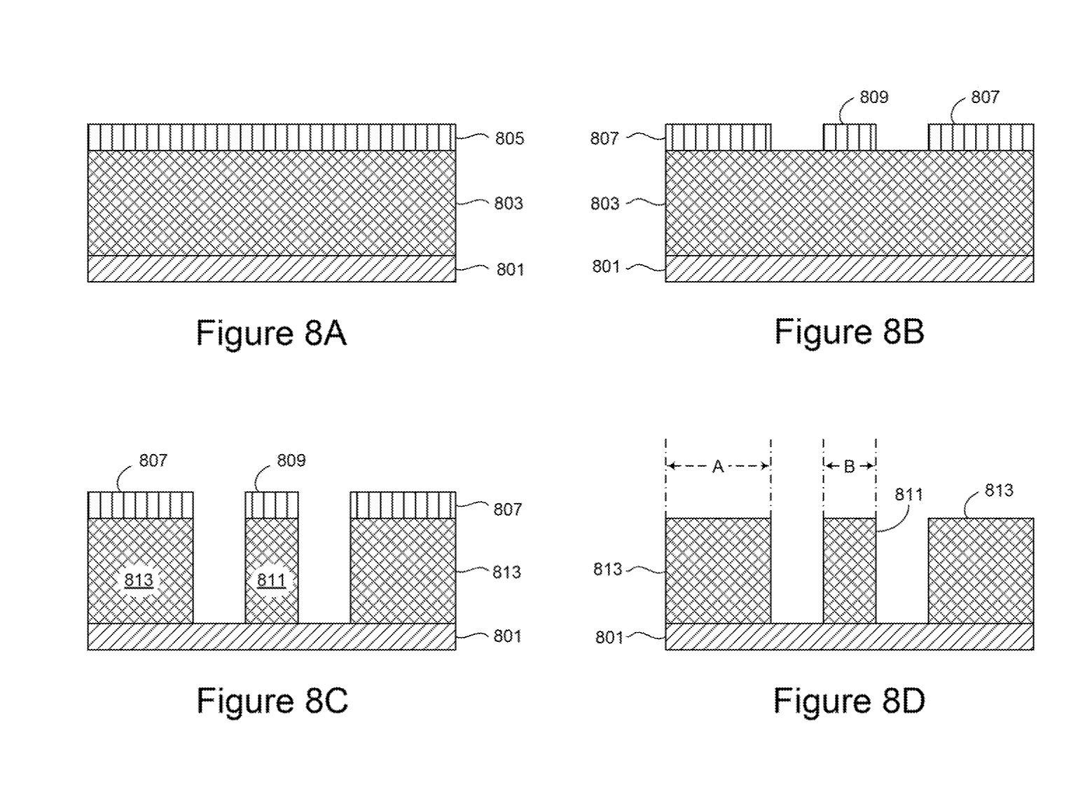

Another example of a method of fabricating a pendulum structure is depicted in FIGS. 8A-8D. FIG. 8A shows a TOX layer 801 on one surface of a silicon slab 803 and a layer of photoresist 805 on an opposite surface of the silicon slab 803. In FIG. 8B, the photoresist has been patterned, leaving, a photoresist portion 807 that defines an outline of a support and a portion 809 that defines an outline of a pendulum. FIG. 8C shows a pendulum 811 and a support 813 that have resulted from etching. In FIG. 8D any remaining photoresist has been removed. In the example given in FIG. 1, the support region 105 of the membrane appears thinner than the pendulum 109, suggesting that the support itself will also be thinner than the pendulum, whereas in the example shown in FIGS. 8A-8D the support 813 appears thicker (dimension A) than the pendulum 811 (dimension B). This is not critical, and the support may be as thick as desired to adequately support the membrane.

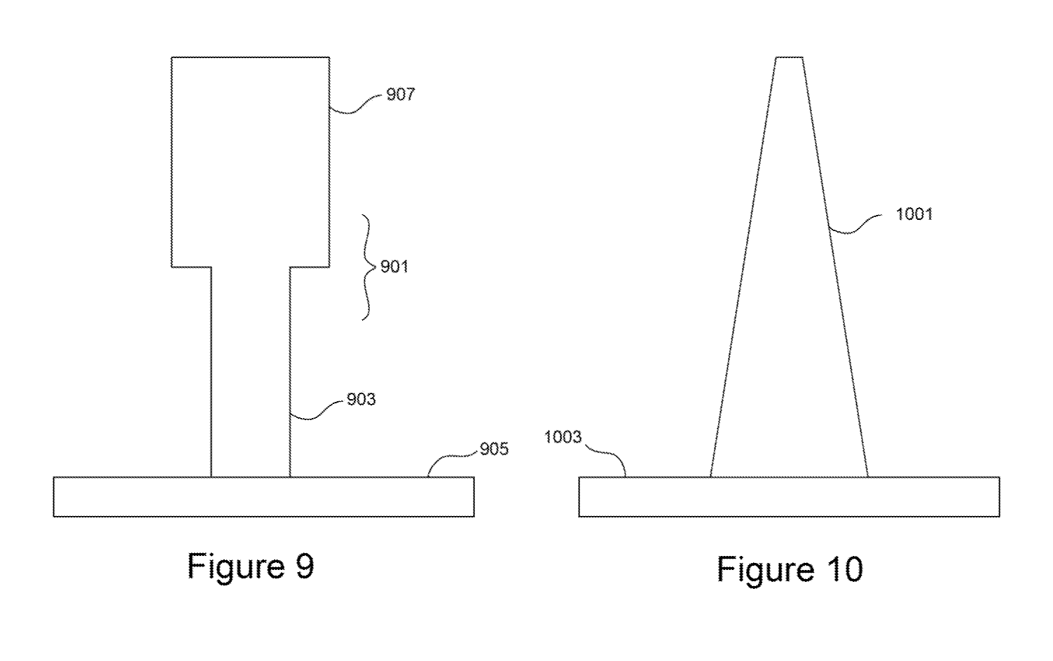

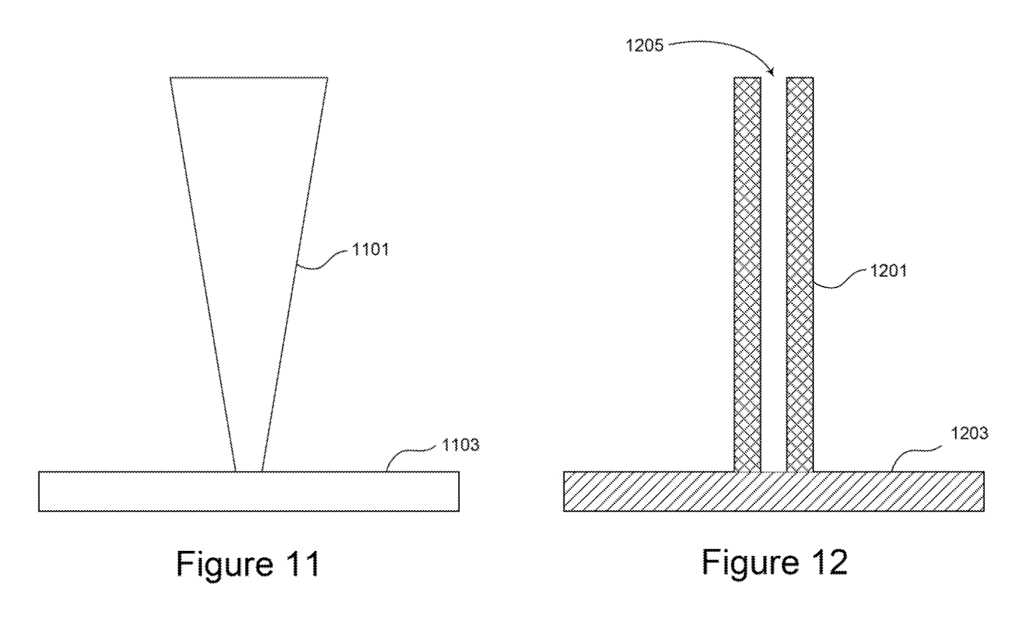

Parameters of some pendulums may vary along the lengths of the pendulums. For example, a pendulum may be less dense near the membrane and more dense further away or the other way around. A relatively high mass material may be deposited on, or otherwise attached to, the end of the pendulum that is further away from the membrane or the end that is closer. The pendulum may be of larger, or smaller, diameter near the membrane than further away. For example, FIG. 9 shows a pendulum generally 901 having a first part 903 attached to a membrane 905 and a second part 907 distal from the membrane. The second pan 907 is more massive, and has a larger diameter, than the first pan 903. The first and second parts may be formed separately and attached to each other, or they may be formed in a single piece of material. FIG. 10 shows a pendulum 1001 on a membrane 1003, the pendulum having a relatively large diameter where it meets the membrane and a diameter that decreases with increasing distance from the membrane. FIG. 11 shows a pendulum 1101 on a membrane 1103, the pendulum having a relatively small diameter where it meets the membrane and a diameter that increases with increasing distance from the membrane.

FIG. 12 shows an example of a hollow pendulum 1201 on a membrane 1203. The pendulum 1201 is tubular, defining an inner space 1205. Such a pendulum may be fabricated, for example, from a carbon nanotube as discussed previously.

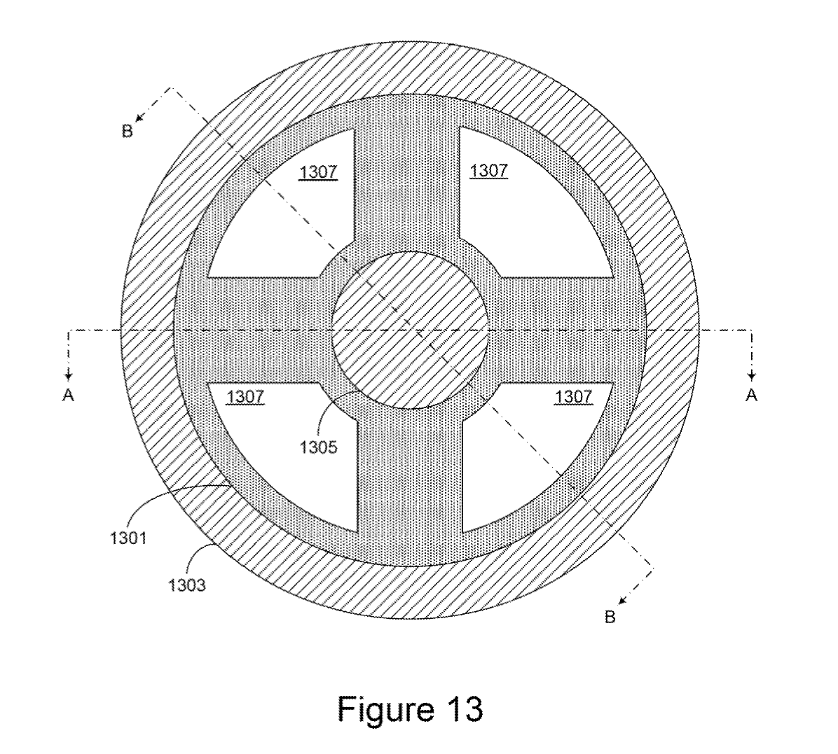

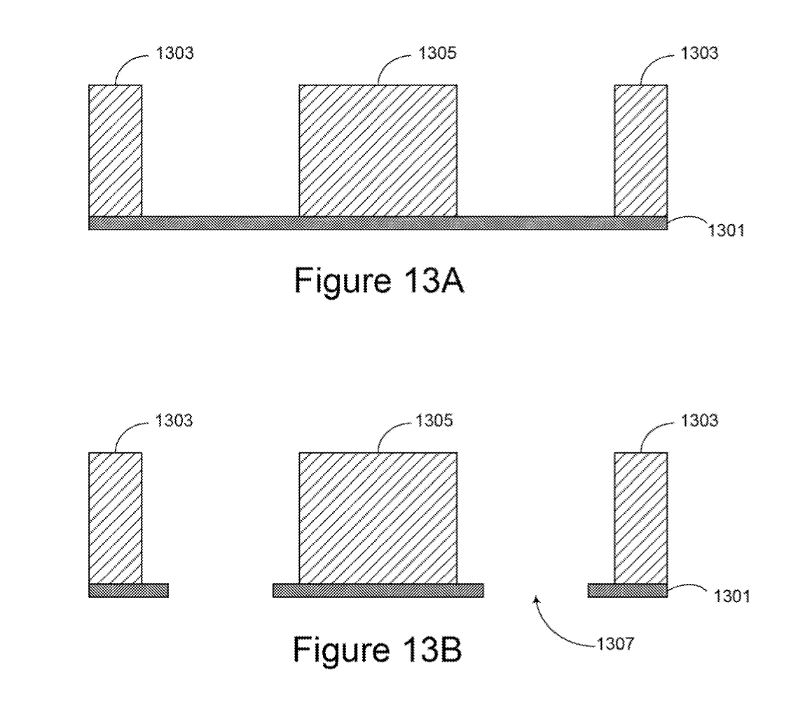

FIGS. 13, 13A, and 13B depict an example in which a membrane 1301 is patterned. One way to do this is to remove portions of the membrane between the support 1303 and the pendulum 1305 leaving empty spaces 1307.

In practical applications, the pendulum may be made to vibrate by electrical, mechanical, or other suitable stimulation. Vibration of the pendulum could be induced by mechanical or other stimulation of the membrane. A plane of vibration may be determined optically (direct or indirect observation of the pendulum), by measuring electrical signals or mechanical parameters resulting from motion of the pendulum, and by observing or measuring motion of the membrane.

A pendulum structure according to the examples described above may be used with many micro-scale structures in which a pendulum would provide advantages. One such application is as a Foucault pendulum that can be used to directly measure angular rotation of an object without any need of measurement of time.

We claim:

1. A micro-scale pendulum structure comprising:
a membrane having a peripheral support portion and an inner portion; and
a micro-scale pendulum carried by the inner portion of the membrane.

2. The structure of claim 1 wherein the membrane comprises a homogeneous amorphous material.

3. The structure of claim 2 wherein the membrane comprises thermally grown oxide.

4. The structure of claim 1 wherein the pendulum comprises silicon.

5. The structure of claim 1 wherein the pendulum comprises a shaft having a substantially constant diameter along its length.

6. The structure of claim 1 and further comprising a support affixed to the support portion of the membrane.

7. The structure of claim 6 wherein the support comprises silicon.

8. The structure of claim 6 wherein the membrane is generally circular in shape and the pendulum is generally centered on and perpendicular to the membrane.

9. The structure of claim 8 wherein the support extends around the membrane and surrounds the pendulum.

10. The structure of claim 1 wherein the membrane comprises a polymer film.

11. The structure of claim 1 wherein the membrane comprises a layered composite material.

12. The structure of claim 1 wherein the membrane comprises a porous material.

13. The structure of claim 1 wherein the pendulum comprises a carbon nanotube.

14. The structure of claim 1 wherein the pendulum comprises a composite of at least two materials.

15. A method of fabricating a micro-scale pendulum structure, the method comprising:
growing a layer of thermal oxide on a surface of a silicon slab;
depositing photoresist on a surface of the silicon slab opposite the thermal oxide;
patterning the photoresist to define a pendulum; and
etching the silicon according to the pattern defined by the photoresist to form the pendulum.
